(19) United States
(12) Patent Application Publication
(10) Pub. No.: US 2026/0090095 A1
(43) Pub. Date: Mar. 26, 2026

(54) STACKED TRANSISTORS HAVING SOURCE/DRAIN CONTACTS AND GATE STRUCTURES WITH LEVEL TOP SURFACES

(71) Applicant: Taiwan Semiconductor Manufacturing Co., Ltd., Hsinchu (TW)

(72) Inventors: Shao-Tse Huang, Hsinchu (TW); Wei-De Ho, Hsinchu (TW); Hsin Yang Hung, New Taipei (TW); Rui-Fu Chen, Hsinchu (TW); Wei-Xiang You, Kaohsiung (TW)

(21) Appl. No.: 19/032,877

(22) Filed: Jan. 21, 2025

Related U.S. Application Data
(60) Provisional application No. 63/699,614, filed on Sep. 26, 2024.

(51) Int. Cl. H10D 84/85; H10D 30/00; H10D 30/01; H10D 62/10; H10D 62/13; H10D 64/23; H10D 84/01

(52) U.S. Cl. CPC H10D 84/856; H10D 30/0191; H10D 30/502; H10D 62/121; H10D 62/151; H10D 64/258; H10D 84/017; H10D 84/0186; H10D 84/851

(57) ABSTRACT

A semiconductor device and the method of forming the same are provided. The semiconductor device may include an isolation region, a first dielectric layer over the isolation region, a second dielectric layer over the first dielectric layer, a first source/drain region in the second dielectric layer, a first nanostructure on a sidewall of the first source/drain region, a first gate electrode around the first nanostructure, a first source/drain contact over the first source/drain region electrically connected to the first source/drain region, a conductive feature in the first dielectric layer and the isolation region, and a dielectric feature over the conductive feature and in the second dielectric layer. A first portion of the first source/drain contact may be between two inner sidewalls of the dielectric feature, and the first portion of the first source/drain contact may be electrically connected to the conductive feature.

### PRIORITY CLAIM AND CROSS-REFERENCE

This application claims the benefit of U.S. Provisional Application No. 63/699,614, filed on Sep. 26, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5, 6A, 6B, 6C, 6D, 7A, 7B, 7C, 7D, 8A, 8B, 8C, 8D, 9A, 9B, 9C, 9D, 10A, 10B, 10C, 10D, 11 A, 11B, 11C, and 11D are various views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising an upper transistor and a lower transistor that are vertically stacked. Each of the upper and lower transistors may include gate structures wrapping around respective semiconductor nanostructures and source/drain regions on sidewalls of the respective semiconductor nanostructures. Source/drain contacts may be on and electrically connected to the source/drain regions. The semiconductor device may further include vertical interconnects and dielectric features on the vertical interconnects. Some of the source/drain contacts may extend through the dielectric features and may be electrically connected to the vertical interconnects. By forming the dielectric features and forming the source/drain contacts extending through the dielectric features, capacitance between the vertical interconnects and adjacent gate structures as well as capacitance between the source/drain contact and adjacent gate structures may be reduced. As a result, the performance of the semiconductor device may be improved.

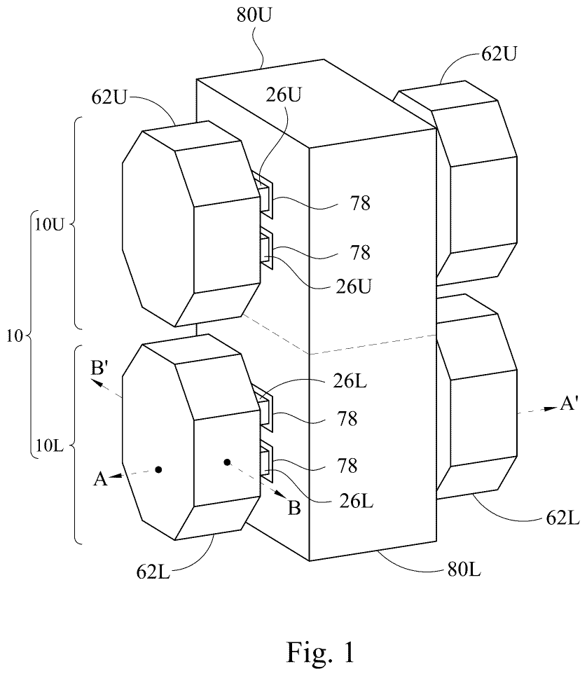

FIG. 1 illustrates an example of a stacking transistor 10, including Field Effect Transistors (FETs) 10U and 10L, in accordance with some embodiments. The stacking transistor 10 may be a Complementary Field-Effect Transistor (CFET), Nano Field-effect Transistor (nano-FET), Fin Field Effect Transistor (fin-FET), or the like. FIG. 1 is a perspective view, and some features of the stacking transistor 10 are omitted for illustrative purposes. The stacking transistor 10 includes multiple vertically stacked FETs. For example, the stacking transistor 10 may include a lower nanostructure-FET 10L of a first device type (e.g., n-type or p-type) and an upper nanostructure-FET 10U of a second device type (e.g., p-type or n-type). In the embodiments where the stacking transistor 10 is a CFET, the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-sections A-A′ and B-B′. Reference cross-section A-A′ may be a vertical cross-section that is parallel to a longitudinal axis of the semiconductor nanostructures 26 of the stacking transistor 10 and in a direction of, for example, a current flow between the source/drain regions 62 of the stacking transistor 10. Reference cross-section A-A′ may be a vertical cross-section that is perpendicular to the reference cross-section B-B′ and extend through the source/drain regions 62. The reference cross-sections A-A′ and B-B′ in FIG. 1 may correspond to the reference cross-sections A-A′ and B-B′ shown in some of the subsequent figures.

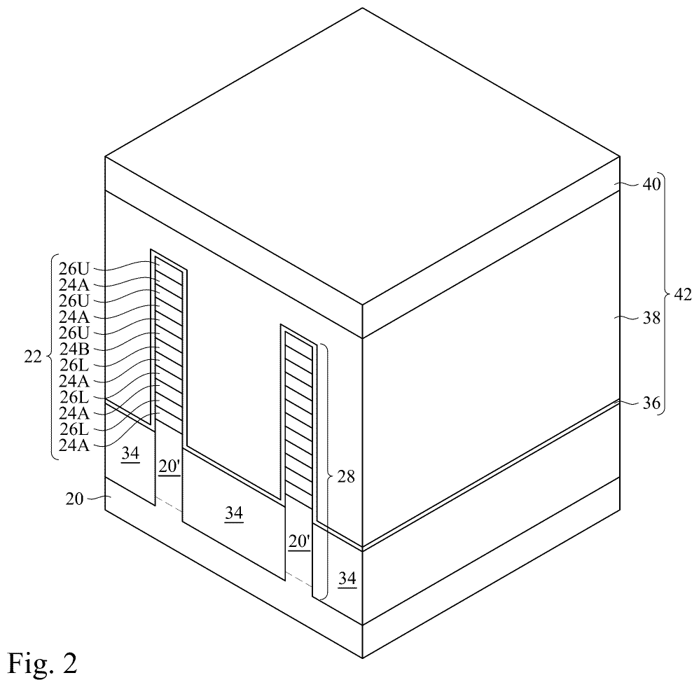

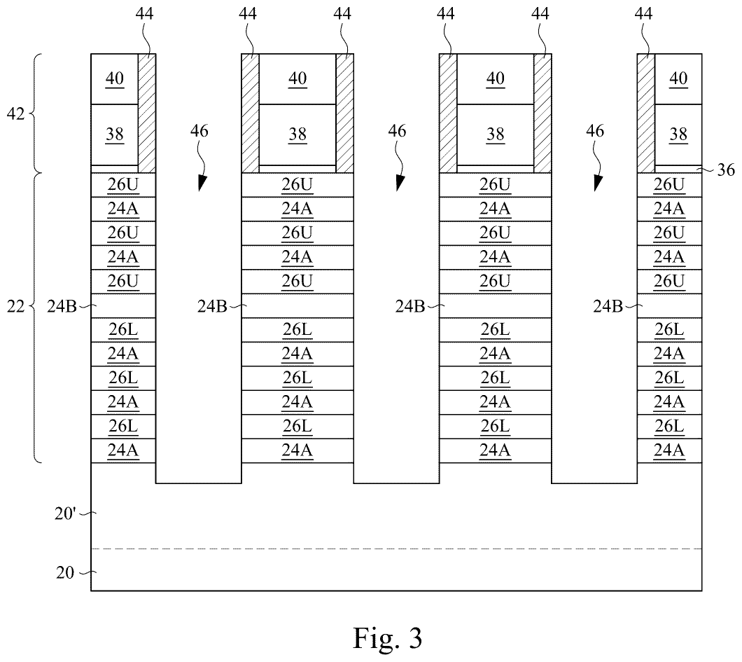

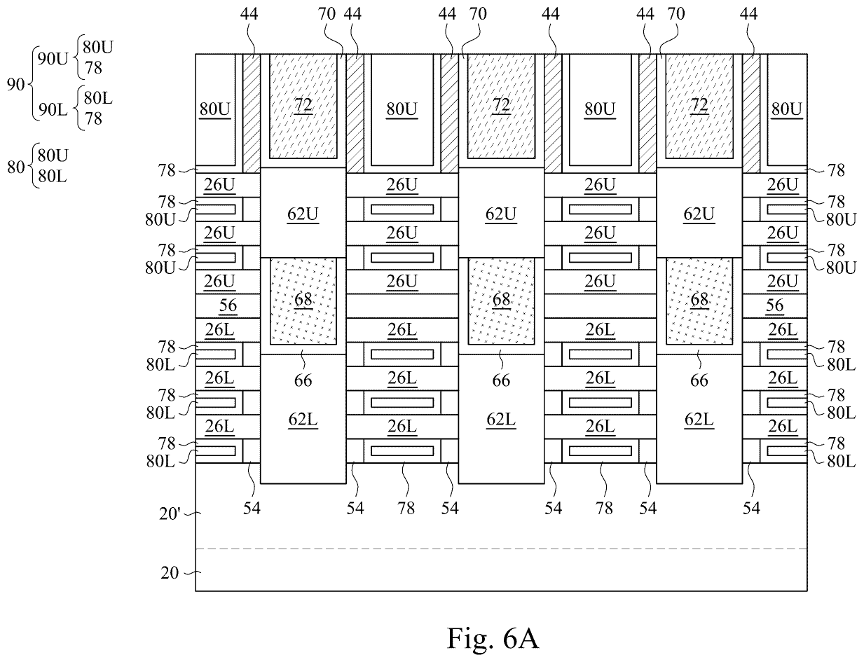

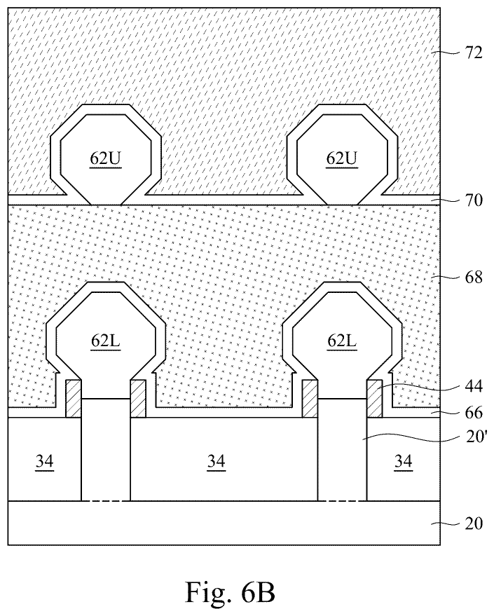

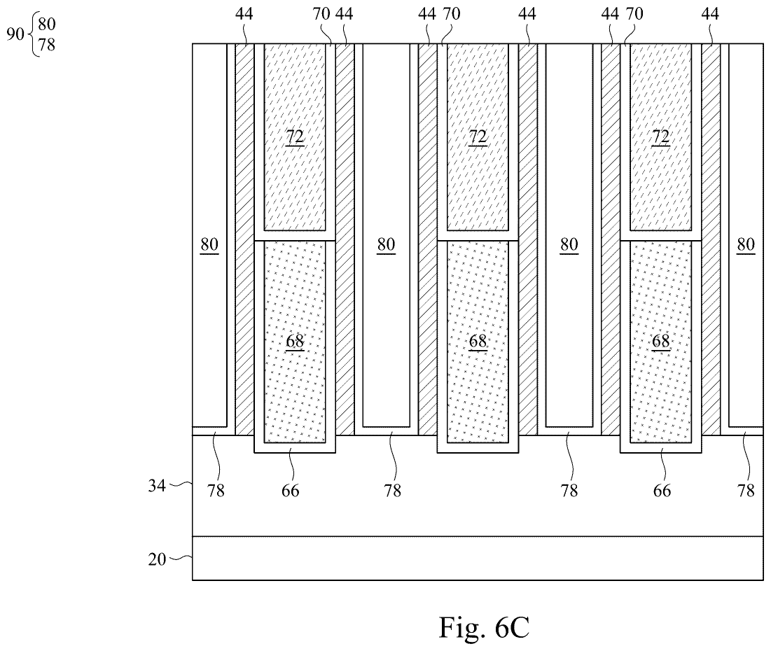

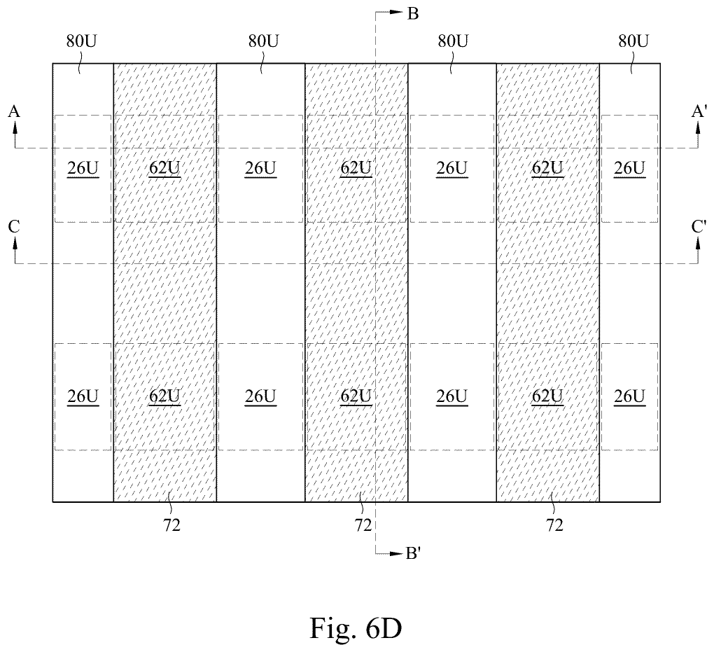

FIGS. 2 through 11D are various views of intermediate stages in the manufacturing of a stacking transistor, which is similar to the one shown in FIG. 1, in accordance with some embodiments. FIG. 2 is a perspective view. FIGS. 6D, 7D, 8D, 9D, 10D, and 11D are top-down views with certain features omitted for illustrative purposes. The reference cross-sections A-A′ and B-B′ shown in FIGS. 6D, 7D, 8D, 9D, 10D, and 11D may correspond to the reference cross-sections A-A′ and B-B′ shown in FIG. 1. FIGS. 3, 4, 5, 6A, 7A, 8A, 9A, 10A, and 11A are cross-sectional views along the reference cross-section A-A′ as shown in FIGS. 1, 6D, 7D, 8D, 9D, 10D, and 11D. FIGS. 6B, 7B, 8B, 9B, 10B, and 11B are cross-sectional views along the reference cross-section B-B′ as shown in FIGS. 1, 6D, 7D, 8D, 9D, 10D, and 11D. FIGS. 6C, 7C, 8C, 9C, 10C, and 11C are cross-sectional views along reference cross-section C-C′ as shown in FIGS. 6D, 7D, 8D, 9D, 10D, and 11D.

In FIG. 2, a wafer, which includes substrate 20, is provided. The substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from a front side of the substrate 20. The side opposite the front side of the substrate 20 may be referred to as the back side of the substrate 20. Each of semiconductor strips 28 includes a semiconductor fin 20′ (patterned portions of the substrate 20) and a multi-layer stack 22 on the semiconductor fin 20′. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26. The dummy nanostructures 24A are between the neighboring lower semiconductor nanostructures 26L as well as between the neighboring upper semiconductor nanostructures 26U. The dummy nanostructures 24B are between the uppermost one of lower semiconductor nanostructures 26L and the lowermost one of the upper semiconductor nanostructures 26U.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will act as channel regions for lower nanostructure-FETs of the stacking transistor. The upper semiconductor nanostructures 26U will act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20′, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 34 are formed over the substrate 20 and between adjacent semiconductor strips 28. The STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric layers(s) are recessed to define the STI regions 34. The dielectric layer(s) maybe recessed such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like.

A mask layer 40 is formed over the planarized dummy gate layer 38, and may include, for example, silicon nitride, silicon oxynitride, or the like. Next, the mask layer 40 may be patterned through photolithography and etching processes to form a mask (not shown), which is then used to etch and pattern dummy gate layer 38, and possibly the dummy dielectric layer 36. The remaining portions of the mask layer 40, the dummy gate layer 38, and the dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The mask layer 40 and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20′. The bottom surfaces of the source/drain recesses 46 may be at a level above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

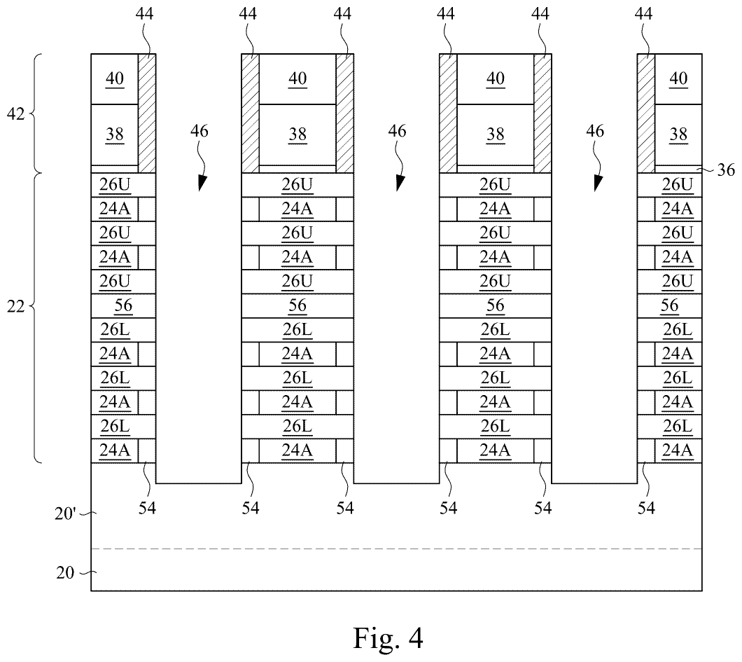

In FIG. 4, the dummy nanostructures 24A are partially removed and the dummy nanostructure 24B are completely removed. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20′. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on the sidewalls the dummy nanostructures 24A, and between the bottom upper semiconductor nanostructures 26U and the top lower semiconductor nanostructures 26L. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

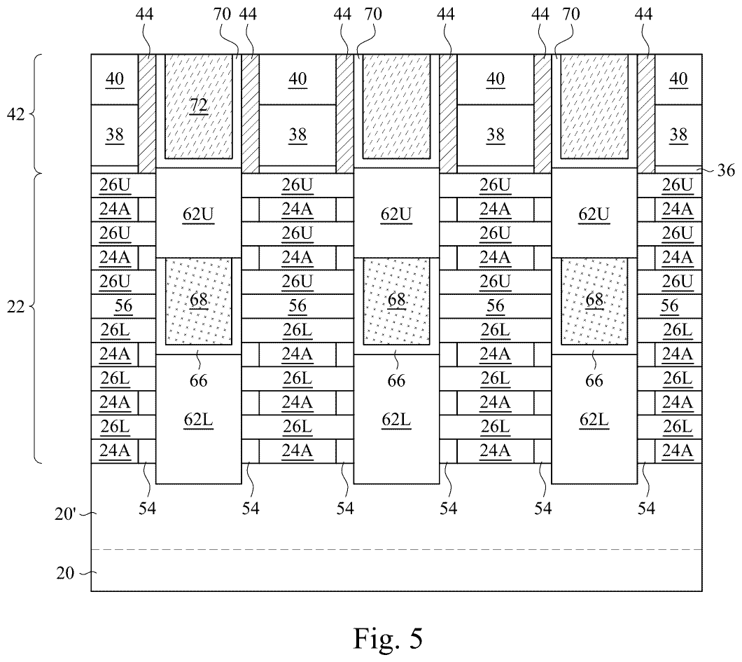

In FIG. 5, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the inner spacers 54, which electrically insulate the lower epitaxial source/drain regions 62L from the dummy nanostructures 24A. The upper epitaxial source/drain regions 62U are in contact with inner spacers 54, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22. In some embodiments, adjacent upper epitaxial source/drain regions 62U remain separated after the epitaxy process is completed. In other embodiments, these facets cause neighboring upper epitaxial source/drain regions 62U of a same FET to merge.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the mask layer 40 (if present) or the dummy gate layers 38 are exposed through the second ILD 72. In the illustrated embodiment, the mask layer 40 remain after the removal process. In other embodiments, the mask layer 40 are removed such that the top surfaces of the dummy gate layers 38 are exposed through the first ILD 68.

In FIGS. 6A through 6D, a gate replacement process to replace the dummy gate stacks 42 and the dummy nanostructures 24A with gate structures 90 is performed. FIG. 6A shows a cross-sectional view that may be obtained along the reference cross section A-A′ shown in the top-down view of FIG. 6D. FIG. 6B shows a cross-sectional view that may be obtained along the reference cross section B-B′ shown in the top-down view of FIG. 6D. FIG. 6C shows a cross-sectional view that may be obtained along the reference cross section C-C′ shown in the top-down view of FIG. 6D. Certain features in FIG. 6D are omitted for illustrative purposes. The upper semiconductor nanostructures 26U and the upper epitaxial source/drain regions 62U are shown in dashed lines in FIG. 6D for illustrative purposes.

The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the material(s) of the semiconductor nanostructures 26. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

Then, gate dielectrics 78 may be deposited in the recesses between the gate spacers 44 and on the exposed semiconductor nanostructures 26. The gate dielectrics 78 may be conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the inner spacers 54.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the lower semiconductor nanostructures 26L. The lower gate electrodes 80L may wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Upper gate electrodes 80U may be formed on the isolation layers described above (if present) or the lower gate electrodes 80L. The upper gate electrodes 80U may be disposed between the upper semiconductor nanostructures 26U. In some embodiments, the upper gate electrodes 80U wrap around the upper semiconductor nanostructures 26U. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

A planarization process may be then performed. The planarization process may be a CMP process, an etch-back process, combinations thereof, or the like. After the planarization process, the top surfaces of the upper gate electrodes 80U, the gate dielectrics 78, the second ILD 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

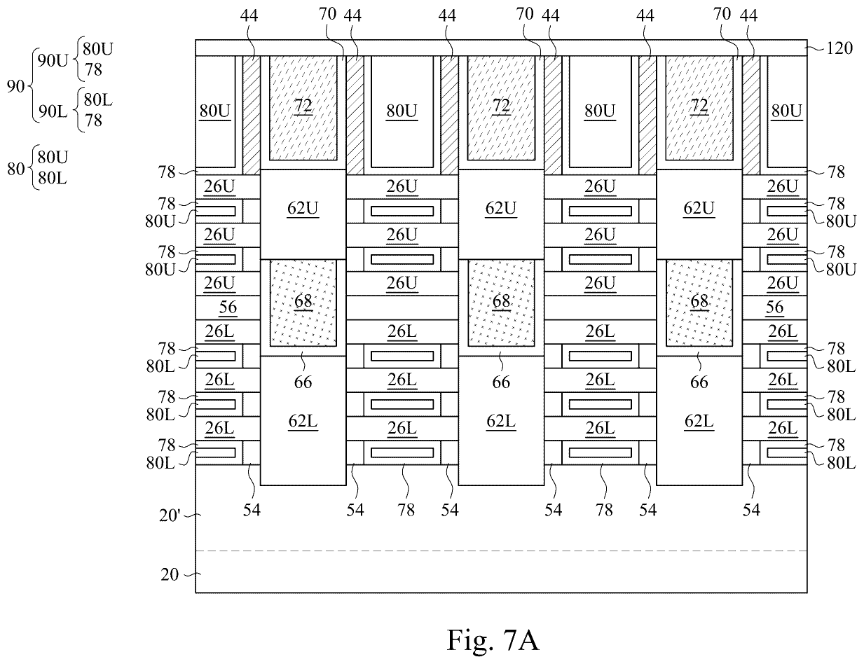

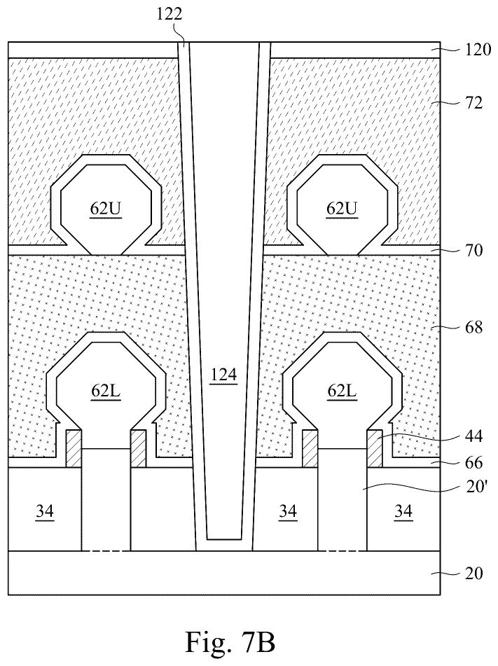

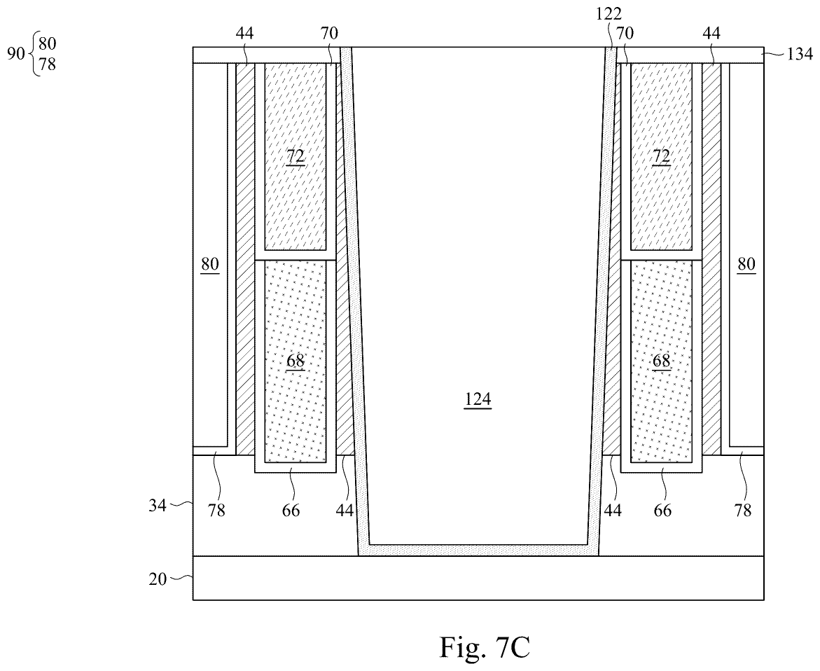

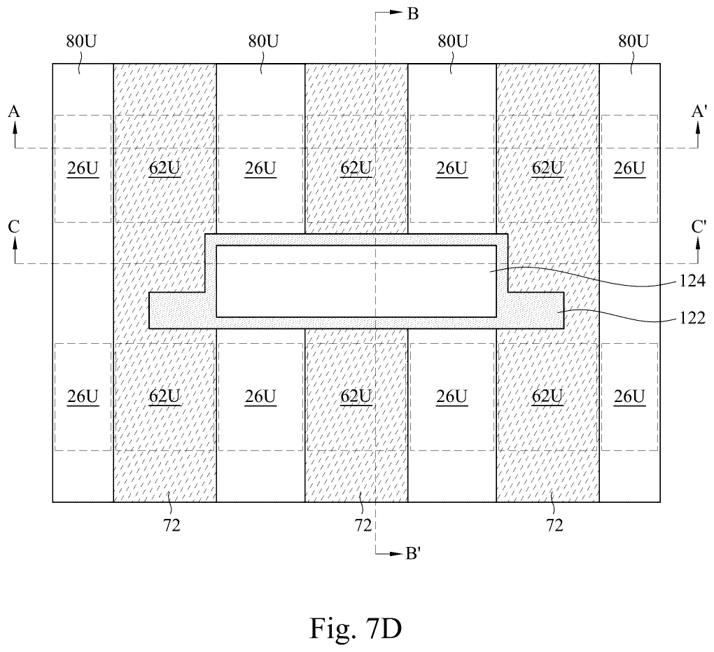

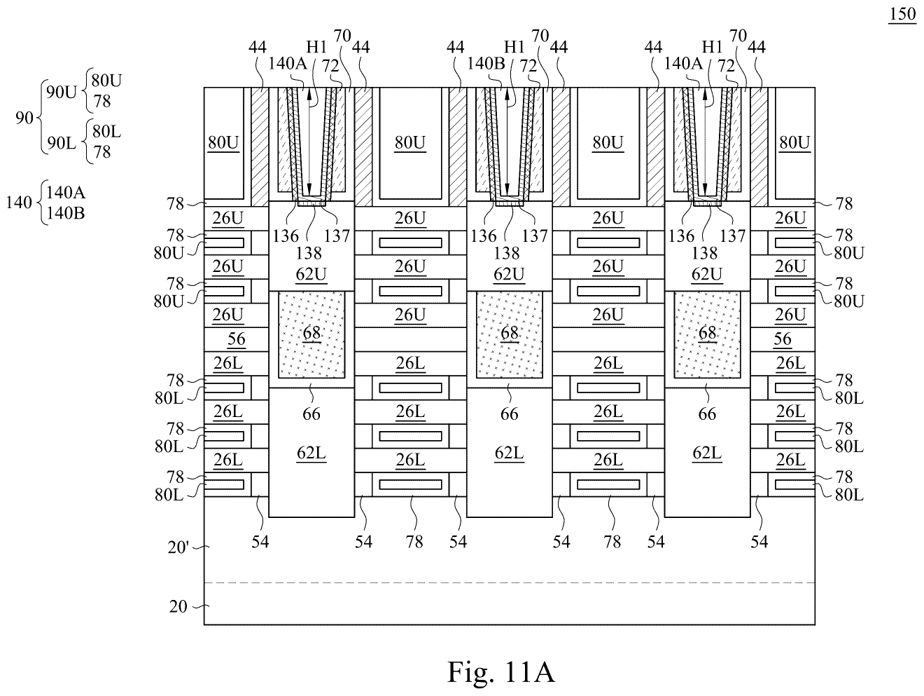

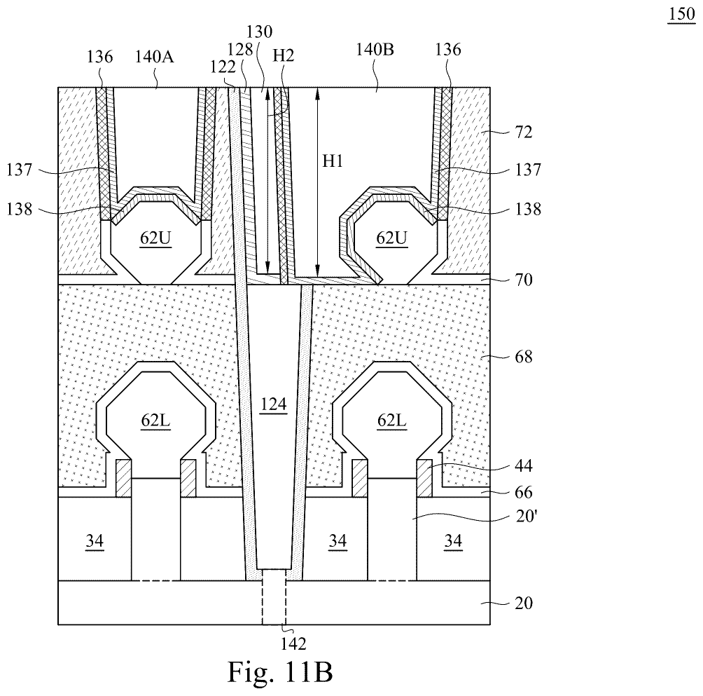

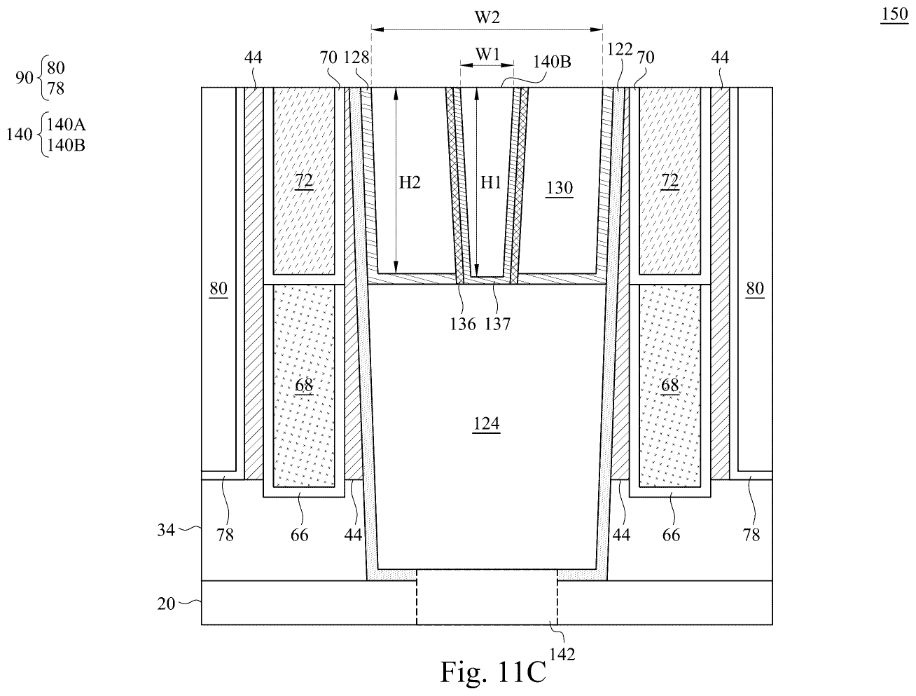

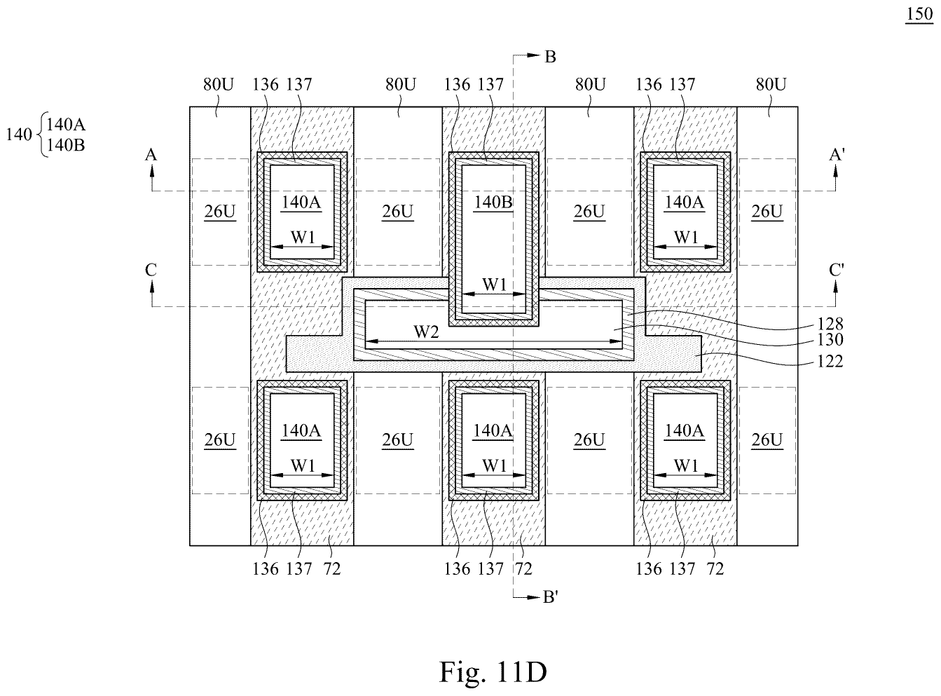

In FIGS. 7A through 7D, a hard mask 120, and a liner 122 and a vertical interconnect 124 are formed through the hard mask 120. The vertical interconnect 124 may electrically connect subsequently formed source/drain contacts 140 (shown in FIG. 11A-11D) over the vertical interconnect 124 to conductive features (not shown) that may be formed on the back side of the substrate 20 of the stacking transistor. FIG. 7A shows a cross-sectional view that may be obtained along the reference cross section A-A′ shown in the top-down view of FIG. 7D. FIG. 7B shows a cross-sectional view that may be obtained along the reference cross section B-B′ shown in the top-down view of FIG. 7D. FIG. 7C shows a cross-sectional view that may be obtained along the reference cross section C-C′ shown in the top-down view of FIG. 7D. Certain features in FIG. 7D are omitted for illustrative purposes. The upper semiconductor nanostructures 26U and the upper epitaxial source/drain regions 62U are shown in dashed lines in FIG. 7D for illustrative purposes.

The liner 122 and the vertical interconnect 124 may extend through the hard mask 120, the second ILD 72, the second CESL 70, the first ILD 68, the first CESL 66, and the STI region 34. The liner 122 may be in contact with the substrate 20. The liner 122 may cover a bottom surface and sidewalls of the vertical interconnect 124 as shown in the cross-sectional views in FIGS. 7B and 7C. The liner 122 may encircle the vertical interconnect 124 as shown in the top-down view in FIG. 7D. The liner 122 may have a shape of a “T” and may include two horizontal protrusions free of the vertical interconnect 124 as shown in the top-down view in FIG. 7D. The liner 122 and the vertical interconnect 124 may also extend through the gate electrodes 80, the gate dielectrics 78, the gate spacers 44. As a result, the liner 122 and the vertical interconnect 124 may act as a gate-cut structure to separate selected gate structure(s) 90, including the gate electrodes 80 and the gate dielectrics 78, into discrete and isolated segments. The shape of the liner 122 discussed above may lead to effective separation of the selected gate structure(s) 90.

The hard mask 120 may be first formed over the gate electrodes 80 and the second ILD 72. The hard mask 120 may be formed of a dielectric material having a high etching selectivity to the material of the second ILD 72, such as silicon nitride, silicon oxide, silicon oxynitride, or the like, which may be formed by any suitable deposition process, such as CVD, ALD, or the like. FIGS. 7A through 7D show embodiments having one hard mask layer over the gate electrodes 80 and the second ILD 72 as an example. In other embodiments, multiple hard mask layers may be formed over the gate electrodes 80 and the second ILD 72. Then the hard mask 120 may be patterned using a suitable photolithography process to form openings that expose selected portions of the gate electrodes 80, the gate dielectrics 78, the gate spacers 44, the second ILD 72, and the second CESL 70.

Then portions the gate electrodes 80, the gate dielectrics 78, the gate spacers 44, the second ILD 72, the second CESL 70, the first ILD 68, the first CESL 66, and the STI region 34 may be removed to form a trench, which may expose a portion of the substrate 20. The removal may include multiple etching processes using various etchants effective for the removal of the materials of the gate electrodes 80, the gate dielectrics 78, the gate spacers 44, the second ILD 72, the second CESL 70, the first ILD 68, the first CESL 66, and the STI region 34. The etching processes may be dry etching processes and the etchants used may include chlorine-based etchants. In some embodiment, the bottom of the trench may be disposed in the STI region 34 and may not expose the substrate 20. In some embodiments, the etching process may remove a portion of the substrate 20.

Then the liner 122 and the vertical interconnect 124 are formed in the trench. The liner 122 may cover surfaces of the trench and the vertical interconnect 124 may cover the surfaces of the liner 122 and fill in the rest of the space of the trench. The liner 122 may comprise a dielectric material, such as silicon oxide, silicon nitride, silicon oxynitride, silicon oxycarbonitride, or the like. The liner 122 may be formed by a suitable deposition process, such as CVD, ALD, or the like. FIGS. 7A through 7D show embodiments having one liner as an example. In other embodiments, multiple liners may be formed between the vertical interconnect 124 and the surfaces of the trench. The vertical interconnect 124 may comprise a conductive material with a resistivity less than about 48 μΩ·cm, such as cobalt, tungsten, molybdenum, copper, ruthenium, the like, or combinations thereof. The conductive material with such a resistivity may lead to lower resistance of the vertical interconnect 124. The vertical interconnect 124 may be formed by a suitable deposition process, such as CVD, PVD, or the like. A planarization process, such as CMP, may be performed to remove excess dielectric and conductive materials formed during the deposition processes on a top surface of the hard mask 120.

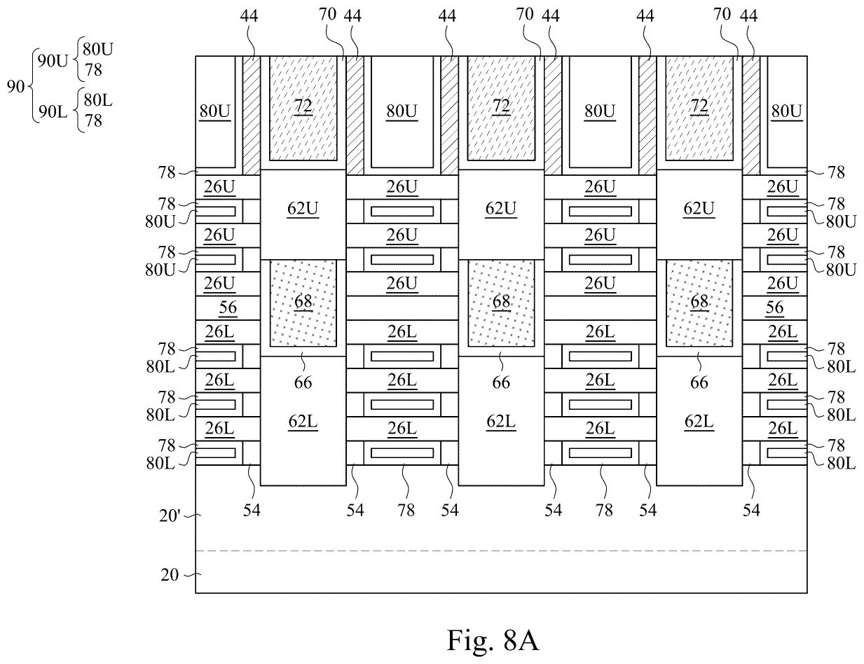

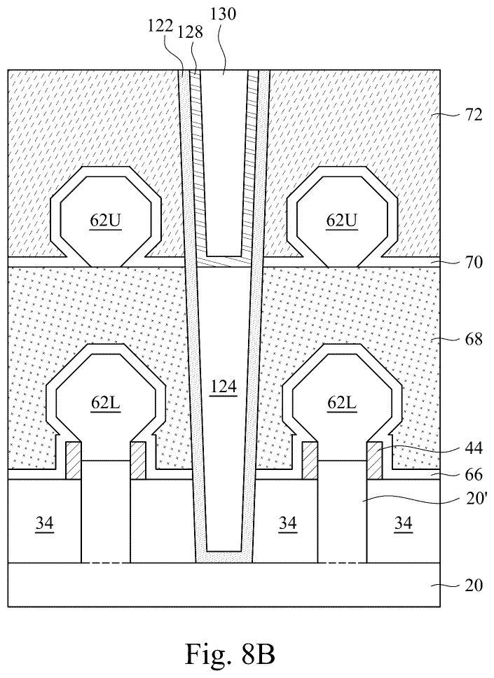

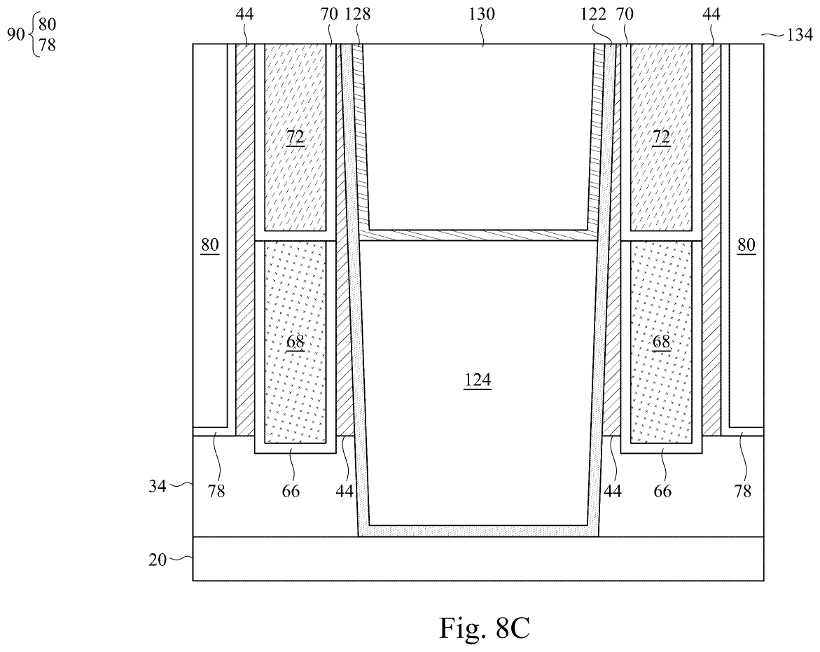

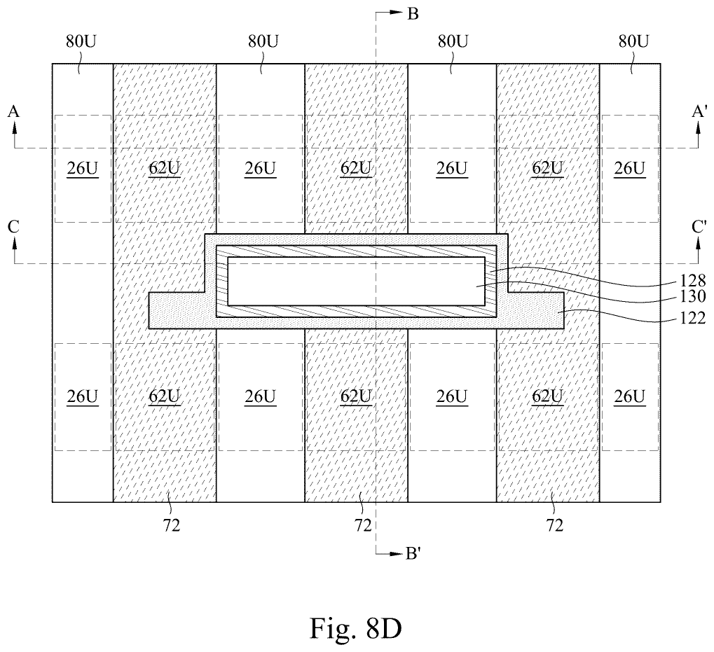

In FIGS. 8A, 8B, 8C, and 8D, a liner 128 and a dielectric feature 130 are formed to replace an upper portion of the vertical interconnect 124, and the hard mask 120 is removed. Replacing an upper portion of the vertical interconnect 124 with the dielectric feature 130 may reduce a volume of the vertical interconnect 124 which may lead to smaller capacitance between the vertical interconnect 124 and the gate electrodes 80, as discussed in greater detail below. FIG. 8A shows a cross-sectional view that may be obtained along the reference cross section A-A′ shown in the top-down view of FIG. 8D. FIG. 8B shows a cross-sectional view that may be obtained along the reference cross section B-B′ shown in the top-down view of FIG. 8D. FIG. 8C shows a cross-sectional view that may be obtained along the reference cross section C-C′ shown in the top-down view of FIG. 8D. Certain features in FIG. 8D are omitted for illustrative purposes. The upper semiconductor nanostructures 26U and the upper epitaxial source/drain regions 62U are shown in dashed lines in FIG. 8D for illustrative purposes.

A trench may be first formed by removing the upper portion of the vertical interconnect 124. The removal may include an etching process that selectively remove the material of the vertical interconnect 124. The etching process may be a dry etching process and the etchants used may include chlorine-based etchants. The etching process may be timed to stop after a certain amount of the material of the vertical interconnect 124 is removed. The trench may expose inner sidewalls of the liner 122. In some embodiments, after the etching process, a top surface of the vertical interconnect 124 is level with a top surface of the first ILD 68 (within process variations).

Then the liner 128 and the dielectric feature 130 are formed in the trench. The liner 128 may cover the top surface of the vertical interconnect 124 and the inner sidewalls of the liner 122, and the dielectric feature 130 may cover surfaces of the liner 122 and fill in the rest of the space of the trench. The liner 128 may cover a bottom surface and sidewalls of the dielectric feature 130 as shown in the cross-sectional views in FIGS. 8B and 8C. In some embodiments, a bottom surface of the liner 128 may be level with a bottom surface of the second CESL 70 (within process variations). The liner 128 may encircle the dielectric feature 130 as shown in the top-down view in FIG. 8D.

The liner 128 may comprise a dielectric material, such as silicon nitride, silicon oxynitride, silicon oxycarbide, silicon oxycarbonitride, or the like. The liner 122 may be formed by a suitable deposition process, such as CVD, ALD, or the like. The dielectric feature 130 may comprise a dielectric material, such as silicon oxide, or the like. In some embodiments, the dielectric feature 130 and the second ILD 72 comprise a same material. The dielectric feature 130 may be formed by a suitable deposition process, such as CVD, ALD, or the like. A planarization process, such as CMP, may be performed to remove excess dielectric materials formed during the deposition processes on the top surface of the hard mask 120 as well as the hard mask 120. After the planarization process, top surfaces of the liner 128, the dielectric feature 130, the liner 122, the second ILD 72, the second CESL 70, the gate spacers 44, the upper gate electrodes 80U, and the gate dielectrics 78 may be substantially coplanar (within process variations).

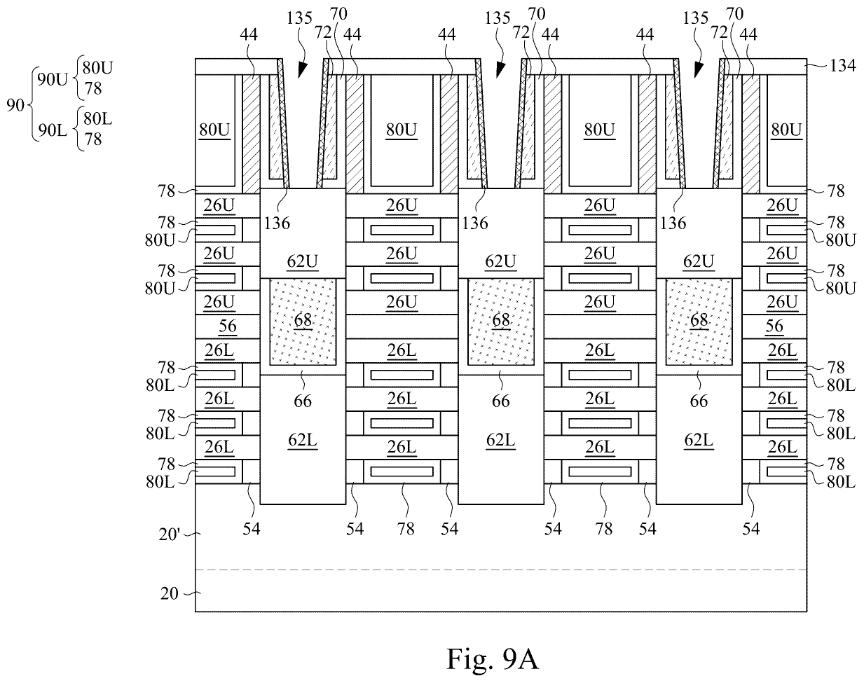

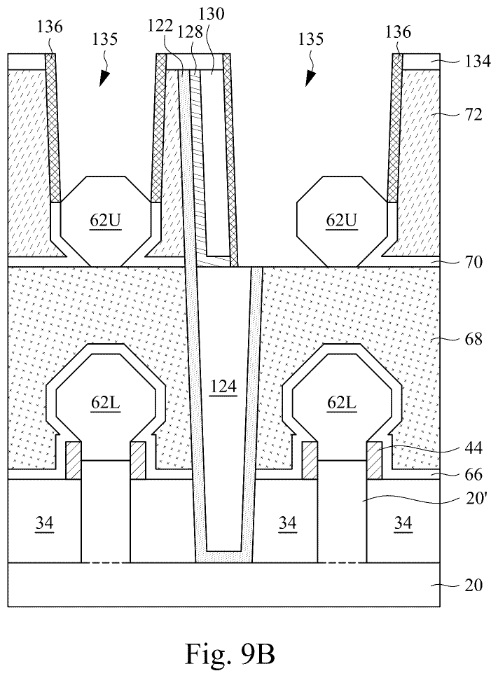

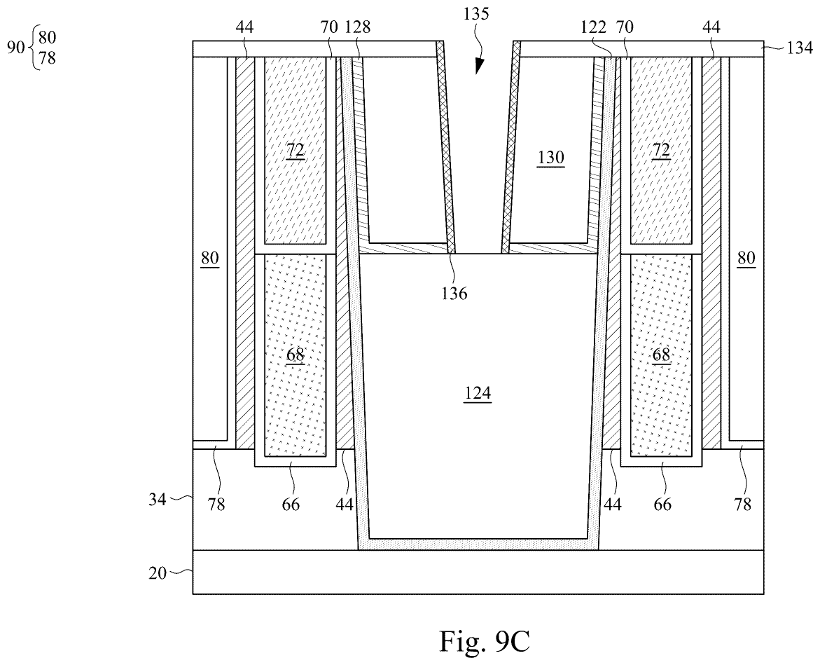

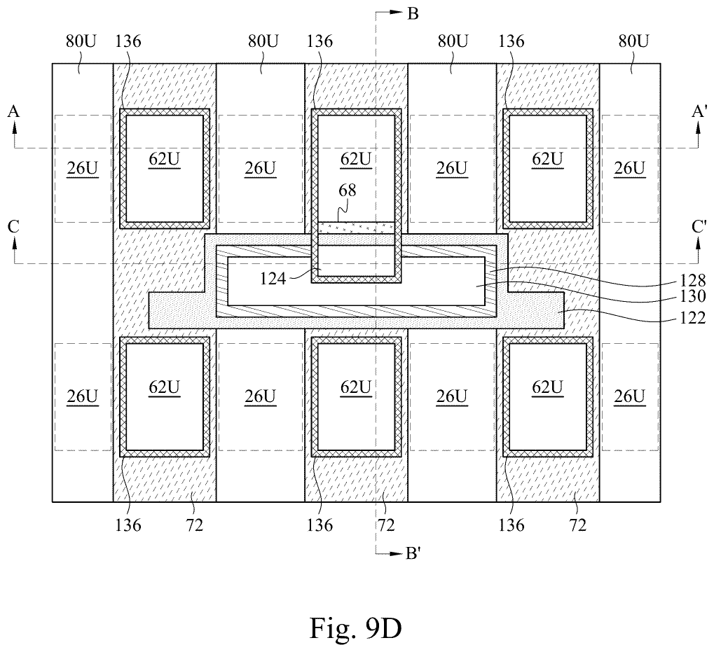

In FIGS. 9A, 9B, 9C, and 9D, a hard mask 134 is formed, openings 135 are formed through the hard mask 134, and liners 136 are formed on sidewalls of the openings 135. FIG. 9A shows a cross-sectional view that may be obtained along the reference cross section A-A′ shown in the top-down view of FIG. 9D. FIG. 9B shows a cross-sectional view that may be obtained along the reference cross section B-B′ shown in the top-down view of FIG. 9D. FIG. 9C shows a cross-sectional view that may be obtained along the reference cross section C-C′ shown in the top-down view of FIG. 9D. Certain features in FIG. 9D are omitted for illustrative purposes. The upper semiconductor nanostructures 26U are shown in dashed lines in FIG. 9D for illustrative purposes.

The hard mask 134 may be first formed over the dielectric feature 130 and the second ILD 72. The hard mask 134 may be formed of a dielectric material having a high etching selectivity to the materials of the dielectric feature 130 and the second ILD 72, such as silicon nitride, silicon oxide, silicon oxynitride, or the like, which may be formed by any suitable deposition process, such as CVD, ALD, or the like. FIGS. 9A through 9D show embodiments having one hard mask layer over the dielectric feature 130 and the second ILD 72 as an example. In other embodiments, multiple hard mask layers may be formed over the dielectric feature 130 and the second ILD 72. Then the hard mask 134 may be patterned using a suitable photolithography process to expose selected portions of the dielectric feature 130, the liner 128, the liner 122, and the second ILD 72.

Then the openings 135 are formed by removing portions the second ILD 72, the second CESL 70, the dielectric feature 130, the liner 128, and the liner 122. After the removal, the openings 135 may extend through the hard mask 134, the second ILD 72, and the second CESL 70, and expose portions of the upper epitaxial source/drain regions 62U. One opening 135 adjacent the dielectric feature 130 may also extend through the liner 128 and the dielectric feature 130, and expose the vertical interconnect 124, the liner 122, the first ILD 68, the liner 128, and the dielectric feature 130. The removal may include multiple etching processes using various etchants effective for the removal of the materials of the second ILD 72, and the second CESL 70, the liner 122, the liner 128, and the dielectric feature 130. The etching processes may be dry etching processes and the etchants used may include chlorine-based etchants.

The liners 136 may comprise a dielectric material, such as silicon nitride, silicon oxynitride, silicon oxycarbide, silicon oxycarbonitride, or the like. The liners 136 may be formed by first performing a suitable deposition process, such as CVD, ALD, or the like. After the deposition process, conformal layers may be formed and cover lower surfaces and the sidewalls of the openings 135. Then an etching process, such as an anisotropic dry etching process, may be performed to remove the lower portions of the conformal layers. After the etching process, the remaining portions of the conformal layers on sidewalls of the openings 135 (including sidewalls of the liner 128 and the dielectric feature 130) may be referred to as the liners 136. After the etching process, the portions of the upper epitaxial source/drain regions 62U, the vertical interconnect 124, the liner 122, the first ILD 68 may be exposed again.

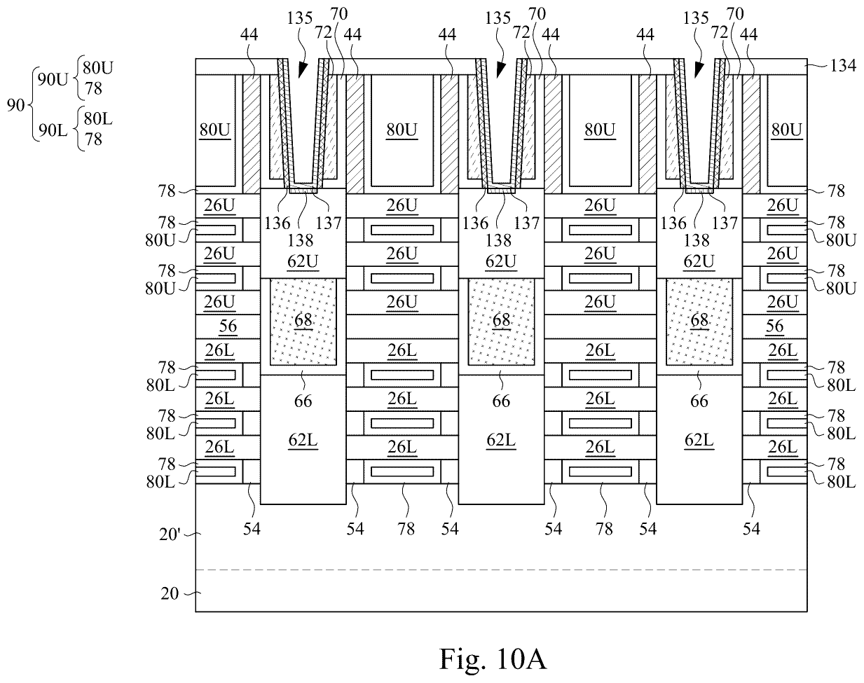

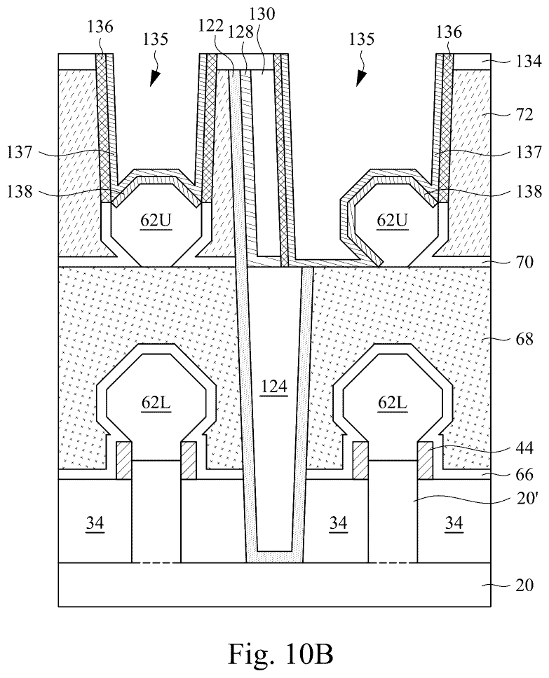

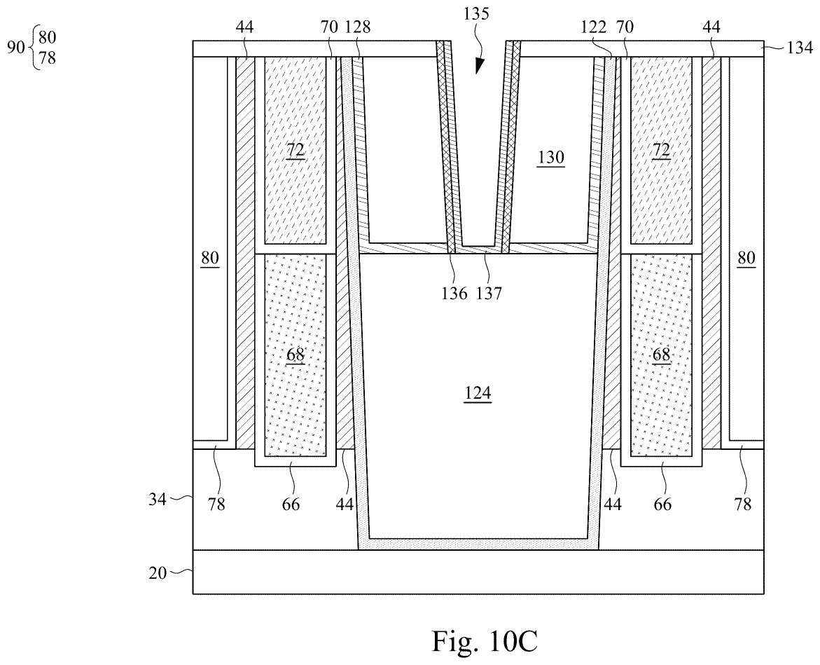

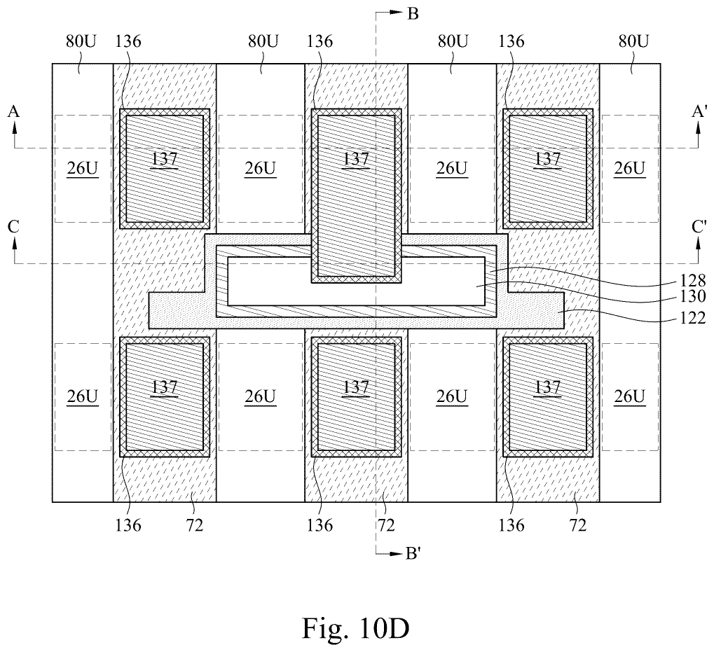

In FIGS. 10A, 10B, 10C, and 10D, metal layers 137 are formed on the sidewalls and lower surfaces of the openings 135, and portions of the upper epitaxial source/drain regions 62U are converted to metal-semiconductor alloy layers 138. FIG. 10A shows a cross-sectional view that may be obtained along the reference cross section A-A′ shown in the top-down view of FIG. 10D. FIG. 10B shows a cross-sectional view that may be obtained along the reference cross section B-B′ shown in the top-down view of FIG. 10D. FIG. 10C shows a cross-sectional view that may be obtained along the reference cross section C-C′ shown in the top-down view of FIG. 10D. Certain features in FIG. 10D are omitted for illustrative purposes. The upper semiconductor nanostructures 26U are shown in dashed lines in FIG. 10D for illustrative purposes.

The metal layers 137 may cover sidewalls of the liners 136, and exposed surfaces of the upper epitaxial source/drain regions 62U, the vertical interconnect 124, the liner 122, and the first ILD 68. The metal layers 137 may comprise a metal material capable of reacting with the semiconductor material of the upper epitaxial source/drain regions 62U, such as nickel, cobalt, titanium, tantalum, platinum, tungsten, zirconium, scandium, yttrium, niobium, molybdenum, ruthenium or the like. The metal layers 137 may be formed by a suitable deposition process such as CVD, PVD, or the like. The metal-semiconductor alloy layers 138 may be between the metal layers 137 and the corresponding upper epitaxial source/drain regions 62U, and improve conductivity between the metal layers 137 and the corresponding upper epitaxial source/drain regions 62U. The metal-semiconductor alloy layers 138 may comprise a silicide material (e.g., titanium silicide, cobalt silicide, nickel silicide, etc.), a germanide material (e.g. titanium germanide, cobalt germanide, nickel germanide, etc.), or the like. The metal-semiconductor alloy layers 138 may formed by performing an annealing process after the metal layers 137 are formed. During the annealing process, the material of the metal layers 137 may react with the material of the upper epitaxial source/drain regions 62U, and convert portions of the upper epitaxial source/drain regions 62U to the metal-semiconductor alloy layers 138.

In FIGS. 11A, 11B, 11C, and 11D, source/drain contacts 140 are formed in the openings 135, and the hard mask 134 is removed. The structure shown in 11A, 11B, 11C, and 11D may be referred to as a stacking transistor 150. FIG. 11A shows a cross-sectional view that may be obtained along the reference cross section A-A′ shown in the top-down view of FIG. 11D. FIG. 11B shows a cross-sectional view that may be obtained along the reference cross section B-B′ shown in the top-down view of FIG. 11D. FIG. 11C shows a cross-sectional view that may be obtained along the reference cross section C-C′ shown in the top-down view of FIG. 11D. Certain features in FIG. 11D are omitted for illustrative purposes. The upper semiconductor nanostructures 26U are shown in dashed lines in FIG. 11D for illustrative purposes.

The source/drain contacts 140 may comprise the source/drain contacts 140A and the source/drain contact 140B. The source/drain contact 140 adjacent the dielectric feature 130 may be referred to as the source/drain contact 140B and the other source/drain contacts 140 may be referred to as the source/drain contacts 140A. The source/drain contacts 140 may be electrically connected to the upper epitaxial source/drain regions 62U through the metal layers 137 and the metal-semiconductor alloy layers 138. The metal layers 137 may cover lower surfaces and sidewalls of the source/drain contacts 140 as shown in the cross-sectional views in FIGS. 11B and 11C. The metal layers 137 may encircle the source/drain contacts 140 as shown in the top-down view in FIG. 11D. Top surfaces of the source/drain contacts 140 and the upper gate electrodes 80U may be level.

The dielectric feature 130 may be between the source/drain contact 140B and an adjacent source/drain contact 140A. A first portion of the source/drain contact 140B may extend through the dielectric feature 130 to electrically connect to the vertical interconnect 124 through the metal layer 137 as shown in cross-sectional view in FIG. 11C. The first portion of the source/drain contact 140B may protrude into a recess of the dielectric feature 130 and may be between two inner sidewalls of the dielectric feature 130 as shown in the top-down view in FIG. 11D. By forming the dielectric feature 130 and forming the source/drain contact 140B through the dielectric feature 130, the volume of the vertical interconnect 124 may be reduced, which may lead to smaller capacitance between the vertical interconnect 124 and the adjacent gate electrodes 80 while maintaining sufficient electrical connection between the vertical interconnect 124 and the upper epitaxial source/drain region 62U as well as conductive features (not shown) that may be formed on the source/drain contacts 140. By forming the source/drain contact 140B through the dielectric feature 130, the source/drain contacts 140A and the source/drain contact 140B may be formed with smaller heights and smaller volumes, which may lead to smaller capacitance between the source/drain contacts 140 and the adjacent upper gate electrodes 80U. As a result, the performance of the stacking transistor 150 may be improved.

The source/drain contacts 140 may have a height H1 smaller than about 50 nm, and the dielectric feature 130 may have a height H2 smaller than about 50 nm. In some embodiments, the height H1 is same as the height H2. The source/drain contacts 140 may have a width W1 in a range from about 1 nm to about 10 nm, and the dielectric feature 130 may have a width W2 in a range from about 10 nm to about 30 nm. In some embodiments, a ratio of the width W2 to the width W1 may be in a range from about 3 to about 10. The source/drain contacts 140 with such dimensions may lead to smaller capacitance between the source/drain contacts 140 and adjacent the upper gate electrodes 80U while maintaining sufficient electrical connection between the upper epitaxial source/drain regions 62U and the conductive features (not shown) that may be formed on the source/drain contacts 140.

The source/drain contacts 140 may comprise a conductive material with a resistivity less than about 60 μΩ·cm, such as may be cobalt, tungsten, molybdenum, copper, ruthenium, the like, or combinations thereof. The source/drain contacts 140 may be formed by a suitable deposition process, such as CVD, PVD, or the like. A planarization process, such as CMP, may be performed to remove excess conductive material formed during the deposition process on the top surface of the hard mask 134 as well as the hard mask 134. After the planarization process, top surfaces of the source/drain contacts 140, the metal layers 137, the liners 136, the dielectric feature 130, the liner 128, the liner 122, the gate spacers 44, the second CESL 70, the second ILD 72, the gate dielectrics 78, the upper gate electrodes 80U, and may be substantially coplanar (within process variations).

After the source/drain contacts 140 are formed, an interconnect structure (not shown) may be formed on the top surfaces of the source/drain contacts 140. The interconnect structure may include dielectric layers and conductive features in the dielectric layers. The conductive features may include conductive lines and vias, which may be electrically connected to the source/drain contacts 140. In some embodiments, after the interconnect structure is formed, the substrate 20 and a bottom portion of the liner 122 are removed in subsequent processes to expose a bottom surface of the vertical interconnect 124. Then a conductive feature 142 (illustrated in dashed lines in FIGS. 11B and 11C) may be formed on the bottom surface of the vertical interconnect 124. The conductive feature 142 may be electrically connected to the vertical interconnect 124.

The embodiments of the present disclosure have some advantageous features. By forming the dielectric feature 130 and forming the source/drain contact 140B through the dielectric feature 130, the capacitance between the vertical interconnect 124 and the adjacent gate electrodes 80 as well as the capacitance between the source/drain contacts 140 and the adjacent upper gate electrodes 80U may be reduced. As a result, the performance of the stacking transistor 150 may be improved.

In an embodiment, a semiconductor device includes an isolation region; a first dielectric layer over the isolation region; a second dielectric layer over the first dielectric layer; a first source/drain region in the second dielectric layer; a first nanostructure on a sidewall of the first source/drain region; a first gate electrode around the first nanostructure; a first source/drain contact over the first source/drain region, wherein the first source/drain contact is electrically connected to the first source/drain region; a conductive feature in the first dielectric layer and the isolation region; and a dielectric feature over the conductive feature and in the second dielectric layer, wherein a first portion of the first source/drain contact is between two inner sidewalls of the dielectric feature, and wherein the first portion of the first source/drain contact is electrically connected to the conductive feature. In an embodiment, top surfaces of the first source/drain contact and the first gate electrode are level. In an embodiment, a top surface of the dielectric feature is level with the top surface of the first source/drain contact. In an embodiment, the first portion of the first source/drain contact extends into a recess of the dielectric feature in a top-down view. In an embodiment, the semiconductor device further includes a metal layer, wherein the metal layer is between the first source/drain contact and the conductive feature, and wherein the metal layer is between the first source/drain contact and first source/drain region. In an embodiment, the semiconductor device further includes a dielectric liner, wherein the dielectric liner is between the conductive feature and the isolation region, wherein the dielectric liner is between the conductive feature and the first dielectric layer, and wherein the dielectric liner is between the dielectric feature and the second dielectric layer. In an embodiment, the semiconductor device further includes a second gate electrode, wherein dielectric feature is between the first gate electrode and the second gate electrode in a top-down view.

In an embodiment, a method of forming a semiconductor device includes depositing an isolation region; forming a first nanostructure; growing a first source/drain region over the isolation region, wherein the first source/drain region is on a sidewall of the first nanostructure; depositing a first dielectric layer over the first source/drain region; forming a first gate electrode over the first nanostructure; forming a trench through the first dielectric layer and into the isolation region; filling a lower portion of the trench with a conductive feature; filling an upper portion of the trench with a dielectric feature over the conductive feature; forming a first opening through the first dielectric layer and the dielectric feature to expose the first source/drain region and the conductive feature; and depositing a first source/drain contact in the first opening, wherein the first source/drain contact is electrically connected to the first source/drain region and the conductive feature, and wherein top surfaces of the first source/drain contact and the first gate electrode are level. In an embodiment, the trench separates the first gate electrode into two discrete segments. In an embodiment, a first portion of the first source/drain contact is between two inner sidewalls of the dielectric feature. In an embodiment, the dielectric feature has a first width and the first portion of the first source/drain contact has a second width, and wherein a ratio of the first width to the second width is in a range from 3 to 10. In an embodiment, the first source/drain contact has a same height as the dielectric feature. In an embodiment, the method further includes forming a second nanostructure; growing a second source/drain region over the isolation region, wherein the second source/drain region is on a sidewall of the second nanostructure; and depositing a second source/drain contact, wherein the second source/drain contact is electrically connected to the second source/drain region, and wherein the dielectric feature is between the first source/drain contact and the second source/drain contact.

In an embodiment, a method of forming a semiconductor device includes: growing a first source/drain region; depositing a first dielectric layer over the first source/drain region; growing a second source/drain region over the first dielectric layer; depositing a second dielectric layer over the second source/drain region; forming a conductive feature in the first dielectric layer beside the first source/drain region; forming a dielectric feature in the second dielectric layer over the conductive feature and beside the second source/drain region; and forming a first source/drain contact in the second dielectric layer, wherein the first source/drain contact is electrically connected to the second source/drain region and the conductive feature, wherein a first portion of the first source/drain contact extends between two inner sidewalls of the dielectric feature. In an embodiment, the first portion of the first source/drain contact extends into a recess of the dielectric feature in a top-down view. In an embodiment, the second dielectric layer and the dielectric feature include a same material. In an embodiment, the method further includes forming a first gate electrode, wherein the second dielectric layer is between the first source/drain contact and the first gate electrode, and wherein top surfaces of the first source/drain contact and the first gate electrode are level. In an embodiment, top surfaces of the conductive feature and the first dielectric layer are level. In an embodiment, the method further includes forming a metal layer, wherein the metal layer is between the first source/drain contact and the conductive feature, wherein the metal layer is between the first source/drain contact and the first dielectric layer, and wherein the metal layer is between the first source/drain contact and first source/drain region. In an embodiment, the method further includes depositing a dielectric liner, wherein the dielectric liner is along sidewalls of the conductive feature and the dielectric feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
an isolation region;
a first dielectric layer over the isolation region;
a second dielectric layer over the first dielectric layer;
a first source/drain region in the second dielectric layer;
a first nanostructure on a sidewall of the first source/drain region;
a first gate electrode around the first nanostructure;
a first source/drain contact over the first source/drain region, wherein the first source/drain contact is electrically connected to the first source/drain region;
a conductive feature in the first dielectric layer and the isolation region; and
a dielectric feature over the conductive feature and in the second dielectric layer, wherein a first portion of the first source/drain contact is between two inner sidewalls of the dielectric feature, and wherein the first portion of the first source/drain contact is electrically connected to the conductive feature.

2. The semiconductor device of claim 1, wherein top surfaces of the first source/drain contact and the first gate electrode are level.

3. The semiconductor device of claim 2, wherein a top surface of the dielectric feature is level with the top surface of the first source/drain contact.

4. The semiconductor device of claim 1, wherein the first portion of the first source/drain contact extends into a recess of the dielectric feature in a top-down view.

5. The semiconductor device of claim 1, further comprising a metal layer, wherein the metal layer is between the first source/drain contact and the conductive feature, and wherein the metal layer is between the first source/drain contact and first source/drain region.

6. The semiconductor device of claim 1, further comprising a dielectric liner, wherein the dielectric liner is between the conductive feature and the isolation region, wherein the dielectric liner is between the conductive feature and the first dielectric layer, and wherein the dielectric liner is between the dielectric feature and the second dielectric layer.

7. The semiconductor device of claim 1, further comprising a second gate electrode, wherein dielectric feature is between the first gate electrode and the second gate electrode in a top-down view.

8. A method of forming a semiconductor device, the method comprising:
depositing an isolation region;
forming a first nanostructure;
growing a first source/drain region over the isolation region, wherein the first source/drain region is on a sidewall of the first nanostructure;
depositing a first dielectric layer over the first source/drain region;
forming a first gate electrode over the first nanostructure;
forming a trench through the first dielectric layer and into the isolation region;
filling a lower portion of the trench with a conductive feature;
filling an upper portion of the trench with a dielectric feature over the conductive feature;
forming a first opening through the first dielectric layer and the dielectric feature to expose the first source/drain region and the conductive feature; and
depositing a first source/drain contact in the first opening, wherein the first source/drain contact is electrically connected to the first source/drain region and the conductive feature, and wherein top surfaces of the first source/drain contact and the first gate electrode are level.

9. The method of claim 8, wherein the trench separates the first gate electrode into two discrete segments.

10. The method of claim 8, wherein a first portion of the first source/drain contact is between two inner sidewalls of the dielectric feature.

11. The method of claim 10, wherein the dielectric feature has a first width and the first portion of the first source/drain contact has a second width, and wherein a ratio of the first width to the second width is in a range from 3 to 10.

12. The method of claim 8, wherein the first source/drain contact has a same height as the dielectric feature.

13. The method of claim 8, further comprising:
forming a second nanostructure;
growing a second source/drain region over the isolation region, wherein the second source/drain region is on a sidewall of the second nanostructure; and
depositing a second source/drain contact, wherein the second source/drain contact is electrically connected to the second source/drain region, and wherein the dielectric feature is between the first source/drain contact and the second source/drain contact.

14. A method of forming a semiconductor device, the method comprising:
growing a first source/drain region;
depositing a first dielectric layer over the first source/drain region;
growing a second source/drain region over the first dielectric layer;
depositing a second dielectric layer over the second source/drain region;
forming a conductive feature in the first dielectric layer beside the first source/drain region;
forming a dielectric feature in the second dielectric layer over the conductive feature and beside the second source/drain region; and
forming a first source/drain contact in the second dielectric layer, wherein the first source/drain contact is electrically connected to the second source/drain region and the conductive feature, wherein a first portion of the first source/drain contact extends between two inner sidewalls of the dielectric feature.

15. The method of claim 14, wherein the first portion of the first source/drain contact extends into a recess of the dielectric feature in a top-down view.

16. The method of claim 14, wherein the second dielectric layer and the dielectric feature comprise a same material.

17. The method of claim 14, further comprising forming a first gate electrode, wherein the second dielectric layer is between the first source/drain contact and the first gate electrode, and wherein top surfaces of the first source/drain contact and the first gate electrode are level.

18. The method of claim 14, wherein top surfaces of the conductive feature and the first dielectric layer are level.

19. The method of claim 14, further comprising forming a metal layer, wherein the metal layer is between the first source/drain contact and the conductive feature, wherein the metal layer is between the first source/drain contact and the first dielectric layer, and wherein the metal layer is between the first source/drain contact and first source/drain region.

20. The method of claim 14, further comprising depositing a dielectric liner, wherein the dielectric liner is along sidewalls of the conductive feature and the dielectric feature.
